(19) United States
(12) Patent Application Publication
(10) Pub. No.: US 2016/0086794 A9
(43) Pub. Date: Mar. 24, 2016

(54) NITROGEN DOPED AMORPHOUS CARBON HARDMASK

(71) Applicant: Applied Materials, Inc., Santa Clara, CA (US)

(72) Inventors: Siu F. CHENG, Culver City, CA (US); Jacob JANZEN, Pasadena, CA (US); Deenesh PADHI, Sunnyvale, CA (US); Bok Hoen KIM, San Jose, CA (US)

(73) Assignee: APPLIED MATERIALS, INC., Santa Clara, CA (US)

(21) Appl. No.: 13/920,944

(22) Filed: Jun. 18, 2013

Related U.S. Application Data
(63) Continuation of application No. 12/750,378, filed on Mar. 30, 2010, now abandoned.

(51) Int. Cl. H01L 21/027; H01L 21/3065

(52) U.S. Cl. CPC H01L 21/0273; H01L 21/3065

(57) ABSTRACT

Embodiments described herein generally relate to the fabrication of integrated circuits and more particularly to nitrogen doped amorphous carbon layers and processes for depositing nitrogen doped amorphous carbon layers on a semiconductor substrate. In one embodiment, a method of forming a nitrogen doped amorphous carbon layer on a substrate is provided. The method comprises positioning a substrate in a substrate processing chamber, introducing a nitrogen containing hydrocarbon source into the processing chamber, introducing a hydrocarbon source into the processing chamber, introducing a plasma-initiating gas into the processing chamber, generating a plasma in the processing chamber, and forming a nitrogen doped amorphous carbon layer on the substrate.

### CROSS-REFERENCE TO RELATED APPLICATIONS

This application is a continuation of co-pending U.S. patent application Ser. No. 12/750,378, filed Mar. 30, 2010, which is herein incorporated by reference in its entirety.

### BACKGROUND OF THE INVENTION

1. Field of the Invention

Embodiments of the present invention generally relate to the fabrication of integrated circuits and more particularly to nitrogen doped amorphous carbon layers and processes for depositing nitrogen doped amorphous carbon layers on a semiconductor substrate.

2. Description of the Related Art

Integrated circuits have evolved into complex devices that can include millions of transistors, capacitors and resistors on a single chip. The evolution of chip design continually requires faster circuitry and greater circuit density. The demand for faster circuits with greater circuit densities imposes corresponding demands on the materials used to fabricate such integrated circuits. In particular, as the dimensions of integrated circuit components are reduced to sub-micron dimensions, it has been necessary to use not only low resistivity conductive materials such as copper to improve the electrical performance of devices, but also low dielectric constant insulating materials, often referred to as low-k dielectric materials. Low-k dielectric materials generally have a dielectric constant of less than 3.8.

Producing devices having low-k dielectric materials with little or no surface defects or feature deformation is problematic. Low-k dielectric materials having a dielectric constant less than about 3.0 are often porous and susceptible to being scratched or damaged during subsequent process steps, thus increasing the likelihood of defects being formed on the substrate surface. Such low-k dielectric materials are often brittle and may deform under conventional polishing processes, such as chemical mechanical polishing (CMP). One solution to limiting or reducing surface defects and deformation of such low-k dielectric materials is the deposition of a hardmask over the exposed low-k dielectric materials prior to patterning and etching. The hardmask prevents damage and deformation of the delicate low-k dielectric materials. In addition, a hardmask layer may act as an etch mask in conjunction with conventional lithographic techniques to prevent the removal of the low-k dielectric material during etch.

Additionally, hardmasks are being used for almost every step in integrated circuit manufacturing processes for both front-end and back-end processes. As device sizes shrink and pattern structure becomes more complex and difficult to manufacture, an etch hardmask is becoming more important as available photoresists are failing to meet the etching resistance requirements and photoresists are simply being used for image transfer rather than as an etch mask in a lithography and etching process. Instead hardmasks that receive the image pattern are becoming the primary material for effective etching of patterns in underlying layers.

Amorphous hydrogenated carbon is a material that may be used as a hardmask for metals, amorphous silicon, and dielectric materials, such as silicon dioxide or silicon nitride materials, among others. Amorphous hydrogenated carbon, also referred to as amorphous carbon and may be denoted as a-C:H or α-C:H, is considered a carbon material with no long-range crystalline order and which may contain substantial hydrogen content, for example on the order of about 10 to 45 atomic % of hydrogen. Amorphous carbon has been observed to have chemical inertness, optical transparency, and good mechanical properties.

As the feature size of device patterns gets smaller, the critical dimension (CD) requirement becomes a more important criterion for stable and repeatable device performance. To achieve the CD requirement it is necessary to use either a more etch resistant and/or thicker mask material, or improve the etch selectivity of the etch process. The former option increases the number of production steps, resulting in higher cost per wafer as well as complex integration issues.

Therefore, there is a need for materials and methods that provide increased etch selectivity such that CD requirements of features may be met.

### SUMMARY OF THE INVENTION

Embodiments of the present invention generally relate to the fabrication of integrated circuits and more particularly to nitrogen doped amorphous carbon layers and processes for depositing nitrogen doped amorphous carbon layers on a semiconductor substrate. In one embodiment, a method of forming a nitrogen doped amorphous carbon layer on a substrate is provided. The method comprises positioning a substrate in a substrate processing chamber, introducing a nitrogen containing hydrocarbon source into the processing chamber, introducing a hydrocarbon source into the processing chamber, introducing a plasma-initiating gas into the processing chamber, generating a plasma in the processing chamber, and forming a nitrogen doped amorphous carbon layer on the substrate.

In another embodiment, a method of forming a device is provided. the method comprises forming one or more nitrogen doped amorphous carbon layers on a substrate by positioning a substrate in a deposition chamber, providing a gas mixture to the deposition chamber, wherein the gas mixture comprises a nitrogen containing hydrocarbon source, one or more hydrocarbon compounds and an inert gas, and generating a plasma in the processing chamber to decompose the one or more hydrocarbon compounds and the nitrogen containing hydrocarbon source in the gas mixture to form the one or more nitrogen doped amorphous carbon layers on the substrate, defining a pattern in at least one region of the one or more nitrogen doped amorphous carbon layers, and transferring the pattern defined in the at least one region of the one or more nitrogen doped amorphous carbon layers into the substrate using the one or more nitrogen doped amorphous carbon layers as a mask.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic representation of a substrate processing system that can be used to perform nitrogen doped amorphous carbon layer deposition according to embodiments described herein;

FIG. 2 is a plot depicting the blanket oxide etch selectivity of a nitrogen doped amorphous carbon layer with varying levels of nitrogen dopant in comparison with previously known amorphous carbon layers;

FIG. 3 is a plot depicting film density (gm/cc) verses the flow rate of nitrogen doped hydrocarbon (sccm);

FIG. 4 is a plot depicting film density (gm/cc) verses deposition temperature (° C.);

FIGS. 5A-5L are schematic side views of one embodiment of a process for using a nitrogen doped amorphous carbon layer as described herein to etch a material layer; and

FIGS. 6A-6H and 6E′ are schematic side views of one embodiment of a process for using a nitrogen doped amorphous carbon layer as described herein in a space mask double patterning process.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to the fabrication of integrated circuits and more particularly to nitrogen doped amorphous carbon layers and processes for depositing nitrogen doped amorphous carbon layers on a semiconductor substrate. In certain embodiments described herein, the nitrogen containing amorphous carbon films exhibit substantially improved blanket etch selectivity (ES) to oxide compared to current state-of-the-art amorphous carbon films. This higher etch selectivity allows for a thinner hardmask thickness which is desirable for 3× nodes and lower.

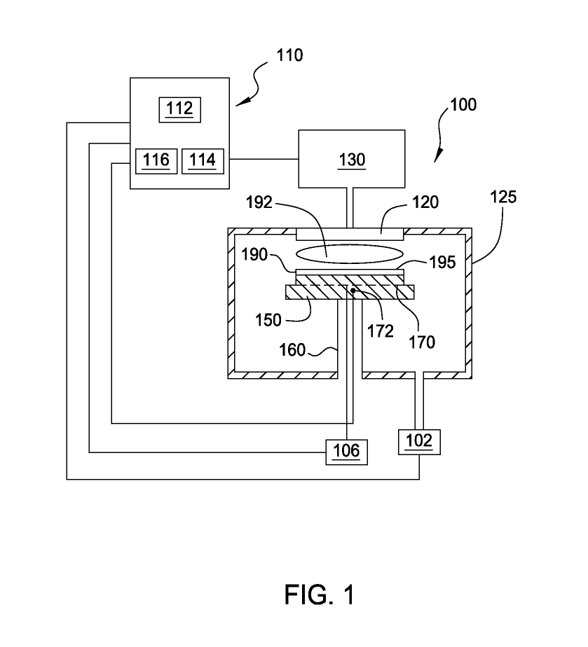

FIG. 1 is a schematic representation of a substrate processing system, system 100, which can be used for amorphous carbon layer deposition according to embodiments described herein. Examples of suitable systems include the CENTURA® systems which may use a DxZ™ processing chamber, PRECISION 5000® systems, PRODUCER™ systems, such as the PRODUCER SE™ processing chamber and the PRODUCER GT™ processing chamber, all of which are commercially available from Applied Materials, Inc., Santa Clara, Calif.

System 100 includes a process chamber 125, a gas panel 130, a control unit 110, and other hardware components such as power supplies and vacuum pumps. Further details of one embodiment of the system used in the embodiments described herein are described in a commonly assigned U.S. patent “High Temperature Chemical Vapor Deposition Chamber”, U.S. Pat. No. 6,364,954, issued on Apr. 2, 2002.

The process chamber 125 generally comprises a substrate support pedestal 150, which is used to support a substrate such as a semiconductor substrate 190. This substrate support pedestal 150 moves in a vertical direction inside the process chamber 125 using a displacement mechanism (not shown) coupled to shaft 160. Depending on the process, the semiconductor substrate 190 can be heated to a desired temperature prior to processing. The substrate support pedestal 150 is heated by an embedded heater element 170. For example, the substrate support pedestal 150 may be resistively heated by applying an electric current from a power supply 106 to the heater element 170. The semiconductor substrate 190 is, in turn, heated by the substrate support pedestal 150. A temperature sensor 172, such as a thermocouple, is also embedded in the substrate support pedestal 150 to monitor the temperature of the substrate support pedestal 150. The measured temperature is used in a feedback loop to control the power supply 106 for the heater element 170. The substrate temperature can be maintained or controlled at a temperature that is selected for the particular process application.

A vacuum pump 102 is used to evacuate the process chamber 125 and to maintain the proper gas flows and pressure inside the process chamber 125. A showerhead 120, through which process gases are introduced into process chamber 125, is located above the substrate support pedestal 150 and is adapted to provide a uniform distribution of process gases into process chamber 125. The showerhead 120 is connected to a gas panel 130, which controls and supplies the various process gases used in different steps of the process sequence. Process gases may include a nitrogen containing hydrocarbon source, a hydrocarbon source, and a plasma-initiating gas and are described in more detail below in conjunction with a description of an exemplary nitrogen doped amorphous carbon layer deposition process.

The gas panel 130 may also be used to control and supply various vaporized liquid precursors. While not shown, liquid precursors from a liquid precursor supply may be vaporized, for example, by a liquid injection vaporizer, and delivered to process chamber 125 in the presence of a carrier gas. The carrier gas is typically an inert gas, such as nitrogen, or a noble gas, such as argon or helium. Alternatively, the liquid precursor may be vaporized from an ampoule by a thermal and/or vacuum enhanced vaporization process.

The showerhead 120 and substrate support pedestal 150 may also form a pair of spaced electrodes. When an electric field is generated between these electrodes, the process gases introduced into chamber 125 are ignited into a plasma 192. Typically, the electric field is generated by connecting the substrate support pedestal 150 to a source of single-frequency or dual-frequency radio frequency (RF) power (not shown) through a matching network (not shown). Alternatively, the RF power source and matching network may be coupled to the showerhead 120, or coupled to both the showerhead 120 and the substrate support pedestal 150.

PECVD techniques promote excitation and/or disassociation of the reactant gases by the application of the electric field to the reaction zone near the substrate surface, creating a plasma of reactive species. The reactivity of the species in the plasma reduces the energy required for a chemical reaction to take place, in effect lowering the required temperature for such PECVD processes.

Proper control and regulation of the gas and liquid flows through the gas panel 130 is performed by mass flow controllers (not shown) and a control unit 110 such as a computer. The showerhead 120 allows process gases from the gas panel 130 to be uniformly distributed and introduced into the process chamber 125. Illustratively, the control unit 110 comprises a central processing unit (CPU) 112, support circuitry 114, and memories containing associated control software 116. This control unit 110 is responsible for automated control of the numerous steps required for substrate processing, such as substrate transport, gas flow control, liquid flow control, temperature control, chamber evacuation, and so on. When the process gas mixture exits the showerhead 120, plasma enhanced thermal decomposition of the hydrocarbon compound occurs at the surface 195 of the semiconductor substrate 190, resulting in the deposition of a nitrogen doped amorphous carbon layer on the semiconductor substrate 190.

Nitrogen Doped Amorphous Carbon Layer Formation

In one embodiment described herein, a nitrogen doped amorphous carbon layer is formed by a process that includes introducing a hydrocarbon source, a nitrogen containing hydrocarbon source, and a plasma-initiating gas into a process chamber, such as processing chamber 125 described above in conjunction with FIG. 1. In one embodiment, the hydrocarbon source is a mixture of one or more hydrocarbon compounds, and, optionally a carrier gas, such as argon. In certain embodiments, the hydrocarbon source is not required and the nitrogen doped amorphous carbon layer is formed by introducing a nitrogen containing hydrocarbon source and a plasma initiating gas.

The hydrocarbon compounds may be partially or completely doped derivatives of hydrocarbon compounds, including fluorine-, oxygen-, hydroxyl group-, and boron-containing derivatives of hydrocarbon compounds.

Hydrocarbon compounds or derivatives thereof that may be included in the hydrocarbon source may be described by the formula CₓH_{y}, where x has a range of between 1 and 10 and y has a range of between 2 and 30.

Suitable hydrocarbon compounds include one or more of the following compounds, for example, alkynes such as acetylene (C₂H₂), propylene (C₃H₆), propyne (C₃H₄), propane (C₃H₈), butane (C₄H₁₀), butylene (C₄H₈), butadiene (C₄H₆), vinylacetylene, phenylacetylene, and derivatives thereof, aromatic hydrocarbons, such as benzene, styrene, toluene, xylene, ethylbenzene, acetophenone, methyl benzoate, phenyl acetate, phenol, cresol, furan, and the like, alpha-terpinene, cymene, 1,1,3,3,-tetramethylbutylbenzene, t-butylether, t-butylethylene, methyl-methacrylate, and t-butylfurfurylether, compounds having the formula C₃H₂ and C₅H₄, halogenated aromatic compounds including monofluorobenzene, difluorobenzenes, tetrafluorobenzenes, hexafluorobenzene and the like. Additional suitable hydrocarbons include alkenes such as ethylene, propylene, butylene, pentene, and the like, dienes such as butadiene, isoprene, pentadiene, hexadiene and the like, and halogenated alkenes include monofluoroethylene, difluoroethylenes, trifluoroethylene, tetrafluoroethylene, monochloroethylene, dichloroethylenes, trichloroethylene, tetrachloroethylene, and the like.

Nitrogen containing hydrocarbon compounds or derivatives thereof that may be included in the nitrogen containing hydrocarbon source may be described by the formula CₓH_{y}N_{z}, where x has a range of between 1 and 12, y has a range of between 2 and 20, and z has a range of between 1 and 10.

Suitable nitrogen containing hydrocarbon compounds include one or more of the following compounds methylamine, dimethylamine, trimethylamine (TMA), triethylamine, aniline, pyridine, and benzonitrile.

Similarly, a variety of gases such as hydrogen (H₂), nitrogen (N₂), ammonia (NH₃), or combinations thereof, among others, may be added to the gas mixture, if desired. Ar, He, and N₂ are used to control the density and deposition rate of the amorphous carbon layer. The addition of H₂ and/or NH₃ can be used to control the hydrogen ratio of the amorphous carbon layer.

In certain embodiments, the nitrogen doped amorphous carbon deposition process includes the use of a plasma-initiating gas that is introduced into the chamber at before and/or same time as the hydrocarbon compound and a plasma is initiated to begin deposition. The plasma-initiating gas may be a high ionization potential gas including to, and not limited to, helium gas, hydrogen gas, nitrogen gas, argon gas and combinations thereof, of which helium gas is preferred. The plasma-initiating gas may also be a chemically inert gas, such as helium gas, nitrogen gas, or argon gas is preferred. Suitable ionization potentials for gases are from about 5 eV (electron potential) to 25 eV. The plasma-initiating gas may be introduced into the chamber before the nitrogen containing hydrocarbon source and/or the hydrocarbon source, which allows a stable plasma to be formed and reduces the chances of arcing. An inert gas used as a diluent gas or a carrier gas, such as argon, may be introduced with the plasma-initiating gas, the nitrogen containing hydrocarbon source, the hydrocarbon source, or combinations thereof.

The hydrocarbon compound and nitrogen containing hydrocarbon compound may be introduced at a hydrocarbon compound to nitrogen containing compound gas molar flow ratio from about 1:10 or greater, for example, from about 1:10 to 10:1, such as from about 1:5 to about 3:1 for the nitrogen doped amorphous carbon deposition. In one embodiment, the hydrocarbon compound to nitrogen containing hydrocarbon compound gas molar flow ratio may be from about 1:2 to about 1:1 for the nitrogen doped amorphous carbon deposition.

The nitrogen doped amorphous carbon layer may be deposited from the processing gas by maintaining a chamber pressure of about 0.5 Torr or greater, such as from about 0.5 Torr to about 20 Torr, and in one embodiment, about 2 Torr or greater, for example, from about 2 Torr to about 4 Torr.

The nitrogen doped amorphous carbon layer may be deposited from the hydrocarbon source and nitrogen doped hydrocarbon source in a chamber maintaining a substrate temperature from about 0° C. to about 800° C., such as at a temperature from about 200° C. to about 650° C. or at a temperature from about 300° C. to about 550° C., for example, from about 400° C. to about 480° C. It has been observed that depositing nitrogen doped amorphous carbon film at increased temperatures yields a denser film which correspondingly improves the etch selectivity of the film.

It has also been observed that the etch selectivity of the deposited nitrogen doped amorphous carbon layer improves with increased electrode spacing between the showerhead and substrate surface when depositing the layer, such as between 200 mils and 5,000 mils spacing, for example, about 500 mils spacing.

In certain embodiments, where a plasma is used, the hydrocarbon source, the nitrogen doped amorphous carbon source, and the plasma-initiating gas are introduced into the chamber and a plasma is initiated to begin deposition. A dual-frequency RF system may be used to generate the plasma. A dual frequency RF power application is believed to provide independent control of flux and ion energy, since it is believed that the energy of the ions hitting the film surface influences the film density. It is believed that the high frequency plasma controls plasma density and a low frequency plasma controls kinetic energy of the ions hitting the substrate surface. A dual-frequency source of mixed RF power provides a high frequency power in a range from about 10 MHz to about 30 MHz, for example, about 13.56 MHz, as well as a low frequency power in a range of from about 10 KHz to about 1 MHz, for example, about 350 KHz. When a dual frequency RF system is used to deposit a nitrogen doped amorphous carbon film, the ratio of the second RF power to the total mixed frequency power is preferably less than about 0.6 to 1.0 (0.6:1). The applied RF power and use of one or more frequencies may be varied based upon the substrate size and the equipment used. In certain embodiments, a single frequency RF power application may be used, and is typically, an application of the high frequency power as described herein.

Plasma may be generated by applying RF power at a power density to substrate surface area of from about 0.01 W/cm² to about 5 W/cm², such as from about 0.8 to about 2.3 W/cm², for example, about 2 W/cm². The power application may be from about 1 Watt to about 2,000 watts, such as from about 800 W to about 1,600 W, for example about 1,400 W for a 300 mm substrate.

An exemplary deposition process for processing 300 mm circular substrates employs a plasma-initiating gas, such as helium and/or argon, a hydrocarbon source, such as acetylene (C₂H₂), and a nitrogen containing hydrocarbon source, such as trimethylamine (N(CH₃)₃). The process may include supplying a plasma-initiating gas, such as helium and/or argon, at a flow rate from about 0 sccm to about 50,000 sccm, for example, between about 400 sccm to about 8,000 sccm, supplying a hydrocarbon source, such as acetylene (C₂H₂), at a flow rate from about 0 sccm to about 50,000 sccm, for example, from about 400 sccm to about 8,000 sccm, and supplying a nitrogen containing hydrocarbon source, such as trimethylamine (N(CH₃)₃), at a flow rate from about 10 sccm to about 10,000 sccm, for example, from about 100 sccm to about 1,000 sccm applying a dual frequency RF power from about 10 W to about 2,000 W, maintaining a chamber pressure from about 0.5 Torr to about 20 Torr, and maintaining a substrate temperature from about 50° C. to about 480° C. This process range provides a deposition rate for a nitrogen doped amorphous carbon layer in the range of about 10 Å/min to about 30,000 Å/min. One skilled in the art, upon reading the disclosure herein, can calculate appropriate process parameters in order to produce a nitrogen doped amorphous carbon film of different deposition rates.

In one embodiment of the deposition process, a plurality of individual amorphous carbon depositions are performed to form a nitrogen doped amorphous carbon layer. In one aspect of the multiple deposition process, a deposition step, such as described herein, is followed by a pause step, in which plasma-initiating gas, a dilution gas, and/or precursor can be flown with a reduced or no deposition rate. A suitable plasma-initiating gas, a dilution gas, and/or precursors can be flown into the chamber at a flow rate from about 0 sccm to about 50,000 sccm. A plasma may be initiated for the pause step if the plasma-initiating gas and/or a dilution gas is used. The deposition and pause steps may then be repeated until a desired thickness is obtained and may be from 1 to 100 cycles, such as from 10 to 50 cycles, for example 30 cycles, or alternatively deposited between about 1% to about 100% of the thickness of the amorphous carbon material, such as from about 2% to about 10% cycles, for example about 3.3%. An individual cycle may deposit nitrogen doped amorphous carbon material from about 1 A to about 1,000 A thickness for each cycle to form a nitrogen doped amorphous carbon layer having a thickness from about 10 A to about 15,000 A. The cyclical deposition process may use one or more of the above described process parameter adjustments.

Alternatively, gases can also be pumped out and flown again before the deposition step or during the pause step.

One major advantage of the nitrogen doped amorphous carbon films is the increase in density over other a-C:H films. Not to be bound by theory but it is believed that the use of a nitrogen containing hydrocarbon precursor which already has a carbon-nitrogen bond is more easily incorporated into the as-deposited film due to the presence of the pre-existing carbon-nitrogen bond in comparison with nitrogen doped amorphous carbon films which are doped using either nitrogen (N₂) or ammonia (NH₃) which do not have a preexisting carbon-nitrogen bonds. It is further believed that incorporation of nitrogen into the as-deposited film decreases the amount of H₂ incorporation into the film thus increasing the nitrogen-carbon bonding network and correspondingly leading to an increase in film density.

Examples of amorphous carbon materials deposited by the processes described herein are as follows.

### COMPARATIVE EXAMPLE 1

A comparative amorphous carbon deposition process example includes providing a flow rate of helium to the processing chamber at about 400 sccm, a flow rate of Argon to the processing chamber at about 14,000 sccm, providing a flow rate of C₂H₂ to the processing chamber at about 600 sccm, applying a high frequency RF power (13.56 MHz) at about 1,400 W, maintaining a deposition temperature of about 400° C., maintaining a chamber pressure of about 3.5 Torr, with a spacing of about 300 mils to produce an amorphous carbon layer having an etch selectivity of about 19.

### COMPARATIVE EXAMPLE 2

A comparative amorphous carbon deposition process example includes providing a flow rate of helium to the processing chamber at about 800 sccm, a flow rate of Argon to the processing chamber at about 1,000 sccm, providing a flow rate of C₃H₆ to the processing chamber at about 2,400 sccm, applying a high frequency RF power (13.56 MHz) at about 1,600 W, maintaining a deposition temperature of about 550° C., maintaining a chamber pressure of about 6 Torr, with a spacing of about 300 mils to produce an amorphous carbon layer having an etch selectivity of about 19.

### EXAMPLE 1

A nitrogen doped amorphous carbon deposition process example includes providing a flow rate of helium to the processing chamber at about 400 sccm, a flow rate of Argon to the processing chamber at about 14,000 sccm, providing a flow rate of C₂H₂ to the processing chamber at about 600 sccm, and providing a flow rate of trimethylamine to the processing chamber at about 200 sccm, applying a high frequency RF power (13.56 MHz) at about 1,400 W, maintaining a deposition temperature of about 400° C., maintaining a chamber pressure of about 3.5 Torr, with a spacing of about 300 mils to produce a nitrogen doped amorphous carbon layer having an etch selectivity of about 24.

### EXAMPLE 2

A nitrogen doped amorphous carbon deposition process example includes providing a flow rate of helium to the processing chamber at about 400 sccm, a flow rate of Argon to the processing chamber at about 14,000 sccm, providing a flow rate of C₂H₂ to the processing chamber at about 600 sccm, and providing a flow rate of trimethylamine to the processing chamber at about 500 sccm, applying a high frequency RF power (13.56 MHz) at about 1,400 W, maintaining a deposition temperature of about 400° C., maintaining a chamber pressure of about 3.5 Torr, with a spacing of about 300 mils to produce a nitrogen doped amorphous carbon layer having an etch selectivity of about 25.

### EXAMPLE 3

A nitrogen doped amorphous carbon deposition process example includes providing a flow rate of helium to the processing chamber at about 400 sccm, a flow rate of Argon to the processing chamber at about 14,000 sccm, providing a flow rate of C₂H₂ to the processing chamber at about 600 sccm, and providing a flow rate of trimethylamine to the processing chamber at about 1,000 sccm, applying a high frequency RF power (13.56 MHz) at about 1,400 W, maintaining a deposition temperature of about 400° C., maintaining a chamber pressure of about 3.5 Torr, with a spacing of about 300 mils to produce a nitrogen doped amorphous carbon layer having an etch selectivity of about 22.

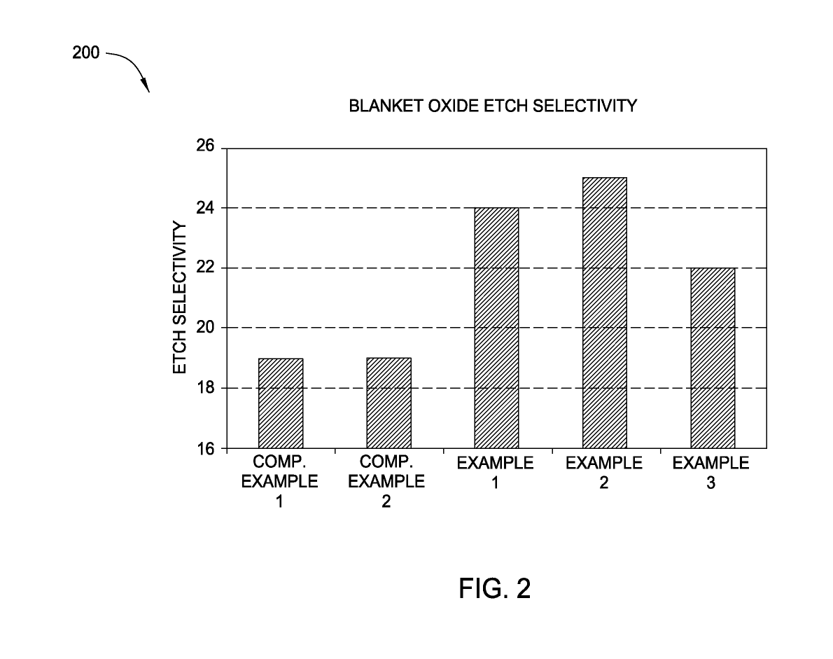

The Blanket Oxide Etch Selectivity results for comparative examples 1 and 2 and examples 1, 2, and 3 are depicted in FIG. 2. FIG. 2 is a plot 200 depicting the blanket oxide etch selectivity of nitrogen doped amorphous carbon layers formed with varying levels of nitrogen dopant in comparison with previously known amorphous carbon layers. The x-axis is labeled as the sample number and the y-axis is labeled as etch selectivity. The results depicted in FIG. 2 demonstrate that varying the nitrogen doping of the nitrogen doped amorphous carbon layer modulates the etch selectivity of the as-deposited film yielding a maximum improvement of about 30% over comparative examples 1 and 2. Example 3 demonstrates that at high flow rates trimethylamine starts to etch the as-deposited film.

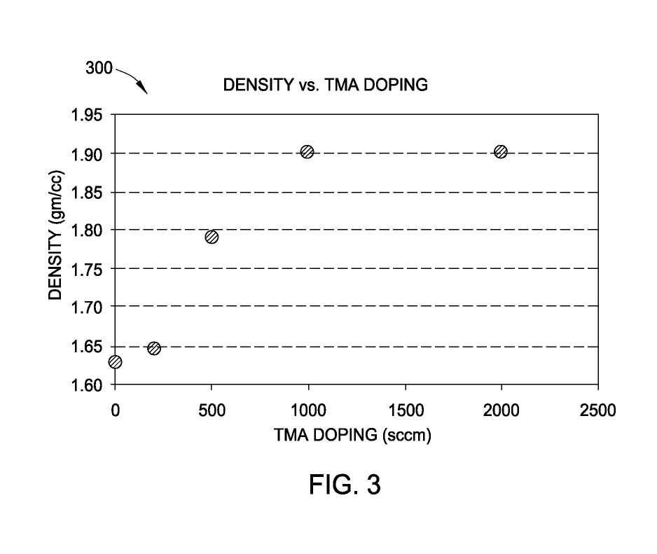

FIG. 3 is a plot 300 depicting film density (gm/cm³) verses the flow rate of nitrogen doped hydrocarbon (sccm). The x-axis is labeled as the trimethylamine doping flow rate (sccm) and the y-axis is labeled as film density (gm/cc). The plot 300 shows that as the flow rate of trimethylamine increases, the density of trimethylamine doped amorphous carbon also increases. Review of FIG. 2 and FIG. 3 also demonstrates that etch selectivity does not necessarily increase linearly with density thus indicating that chemical bonding also contributes to etch selectivity.

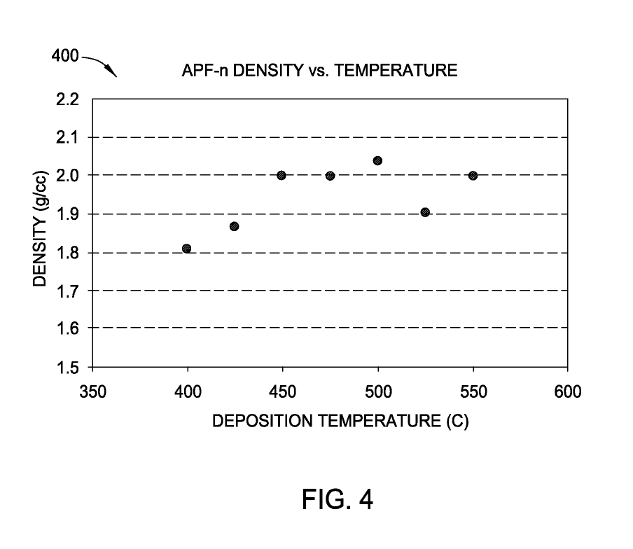

FIG. 4 is a plot 400 depicting film density (gm/cm³) verses deposition temperature (° C.). The x-axis is labeled as deposition temperature (° C.) and the y-axis is labeled as film density (gm/cc). The plot 400 demonstrates that the film density can be increased by further increasing the deposition temperature.

Table I summarizes the film properties for comparative example 1, comparative example 2, and example 2.

TABLE I

| | Comparative | Comparative | Example 2 |
|---|---|---|---|
| | Example 1 | Example 2 | (500 sccm TMA) |
| Deposition | 400 | 550 | 400 |
| Temperature (° C.) | | | |
| Density | 1.58 | 1.55 | 1.72 |
| (gram/cm³) | | | |
| Stress (MPa) | −390 | 70 | −660 |
| n633 | 2.10 | 1.86 | 2.01 |
| k633 | 0.30 | 0.38 | 0.41 |
| Deposition Rate | 3,650 | 2,000 | 1,080 |
| (Å/min) | | | |

In one embodiment, the as-deposited nitrogen doped amorphous carbon layer has an adjustable carbon:nitrogen ratio that ranges from about 0.01% nitrogen to about 10.0% nitrogen. In one embodiment, the as-deposited nitrogen doped amorphous carbon layer has an adjustable carbon:nitrogen ratio that ranges from about 0.1% nitrogen to about 4.0% nitrogen. In one embodiment, the as-deposited nitrogen doped amorphous carbon layer has an adjustable carbon:nitrogen ratio that ranges from about 1.5% nitrogen to about 2% nitrogen. Controlling the nitrogen ratio of the amorphous carbon layer is desirable for tuning the films etch selectivity.

Other deposition chambers are within the scope of the invention and the parameters listed above may vary according to the particular deposition chamber used to form the amorphous carbon layer. For example, other deposition chambers may have a larger or smaller volume, requiring gas flow rates that are larger or smaller than those recited for deposition chambers available from Applied Materials, Inc.

Nitrogen Doped Amorphous Carbon Hardmask

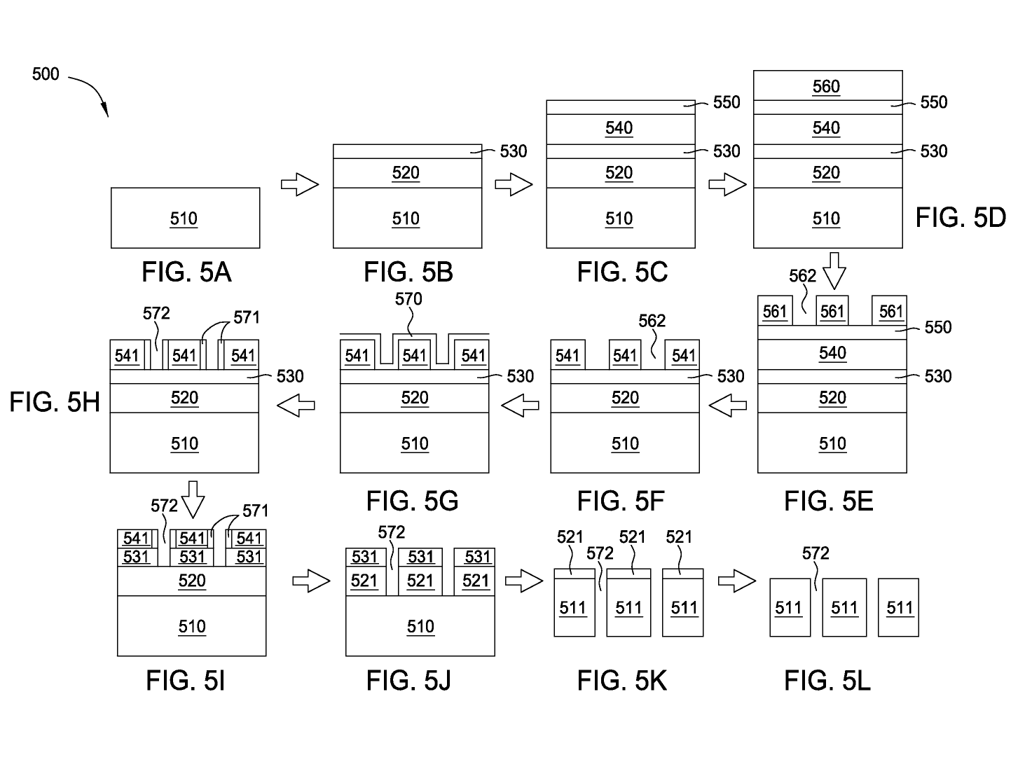

FIGS. 5A-5I are schematic side views of a process for using a nitrogen doped amorphous carbon layer as described herein to etch a material layer. A base material 510 is deposited on a substrate surface (not shown) to begin forming a material stack 500. The base material may be one or more materials used in forming semiconductor devices including a silicon substrate material, an oxide material, a polysilicon material, or the like. A first nitrogen doped amorphous carbon layer 520 is deposited on the base material 510 and a first anti-reflective coating material 530 is deposited on the first nitrogen doped amorphous carbon layer 520 as shown in FIG. 5B. The first anti-reflective coating material 530 is used to control the reflection of light during a lithographic patterning process. The first anti-reflective coating material 530 may comprise silicon dioxide, silicon oxynitride, silicon nitride, or combinations thereof. The anti-reflective coating material may be a DARC™ material layer commercially available from Applied Materials, Inc. of Santa Clara, Calif.

A second nitrogen doped amorphous carbon layer 540 and a second antireflective coating material 550 may be deposited sequentially on the first antireflective coating material as shown in FIG. 5C. The second nitrogen doped amorphous carbon layer 540 and second antireflective coating material 550 may be the same materials as deposited for layer 520 and first anti-reflective coating material 530. A resist layer 560, such as a photoresist material, is then deposited on the second antireflective coating material 550 as shown in FIG. 5D. The resist layer is then patterned by a lithographic process producing a patterned resist layer 561 as shown in FIG. 5E. The first pattern 562 formed in the resist layer 561 is transferred to the second nitrogen doped amorphous carbon layer 540 to form a patterned second nitrogen doped amorphous carbon layer 541 by first etching the second antireflective coating material 550 and then the second nitrogen doped amorphous carbon layer 540 by one or more etching processes as shown in FIG. 5F. The patterned second nitrogen doped amorphous carbon layer 541 may perform as a hardmask for the underlying material. The second antireflective coating material 550 may be removed by the one or more etching processes or by a separate process.

A third nitrogen doped amorphous carbon layer 570 is deposited on the first antireflective coating material 530 and the patterned second amorphous carbon layer 541 as shown in FIG. 5G. The third nitrogen doped amorphous carbon layer may be deposited by any of the processes described herein. The third nitrogen doped amorphous carbon layer 570 is patterned by an anisotropic etch process to provide for sidewall nitrogen doped amorphous carbon materials 571 as shown in FIG. 5H. The presence of the sidewall nitrogen doped amorphous carbon materials 571 allows for the formation of a second pattern 572 with reduced critical dimensions and feature sizes, i.e., increased pattern density, than can otherwise normally be achieved through current photolithographic processes. The patterned second nitrogen doped amorphous carbon layer 541 in combination with the sidewall nitrogen doped amorphous carbon materials 571 may perform as a hardmask layer for the underlying first anti-reflective coating material 530 and the first nitrogen doped amorphous carbon layer 520.

The first antireflective coating material 530 is then etched to form a patterned antireflective coating layer 531 with the second pattern 572 as shown in FIG. 5I. The patterned second nitrogen doped amorphous carbon layer 541 and the sidewall nitrogen doped amorphous carbon materials 571 are removed during the etching process or by a subsequent process. The first nitrogen doped amorphous carbon layer 520 is then etched to form a patterned first nitrogen doped amorphous carbon layer 521 having the second pattern 572 to be transferred to the underlying base material 510. The base material 510 is then etched using the patterned first nitrogen doped amorphous carbon layer 521 as a hardmask layer as shown in FIG. 5K and the patterned first nitrogen doped amorphous carbon layer 521 is removed to provide a substrate surface with a patterned base material 511 having the second pattern 572 as shown in FIG. 5L.

In an alternative embodiment, a patterned resist material is used in place of the patterned second nitrogen doped amorphous carbon layer 541 for FIGS. 5F-5L, thereby eliminating the need for the patterned second nitrogen doped amorphous carbon layer 540 and a second antireflective coating material 550 and the corresponding deposition steps and etching steps of FIGS. 5C-5E. In certain embodiments, any of the nitrogen doped amorphous carbon layers may be replaced with an amorphous carbon layer, such as an Advanced Patterning Film™ (APF) material commercially available from Applied Materials, Inc. of Santa Clara, Calif.

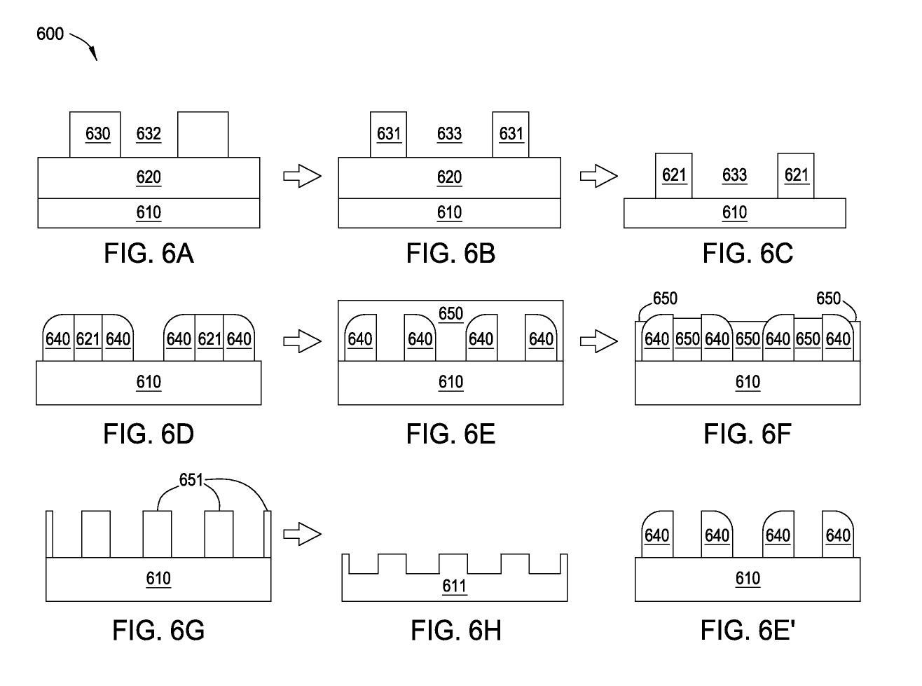

FIGS. 6A-6H are schematic side views of a process for using a nitrogen doped amorphous carbon layer as described herein in a space mask double patterning process. A base material 610 is deposited on a substrate surface to begin forming a material stack 600. The base material may be one or more materials used in forming semiconductor devices including a silicon substrate material, an oxide material, a polysilicon material, or the like. A first nitrogen doped amorphous carbon layer 620 is deposited on the base material 610 and a patterned resist layer 630 having a first pattern 632 is formed on the first nitrogen doped amorphous carbon layer 620 as shown in FIG. 6A. The amorphous carbon layer may be an Advanced Patterning Film™ (APF) material commercially available from Applied Materials, Inc. of Santa Clara, Calif., or alternatively, a nitrogen doped amorphous carbon material as described herein. The resist layer 630 may be patterned by a lithographic process. The patterned resist layer 630 is then subjected to a trimming process, thereby, narrowing the width of the patterned resist materials to form a second pattern 633 defined by the trimmed resist material 631 as shown in FIG. 6B. The first nitrogen doped amorphous carbon layer 620 is then etched to transfer the second pattern 633 to form a patterned nitrogen doped amorphous carbon layer 621 as shown in FIG. 6C.

Sidewall spacers 640 are then formed adjacent the patterned nitrogen doped amorphous carbon layer 621 structures. Spacers may comprise an etchable material having an etching rate different from the first amorphous carbon layer or conformal amorphous carbon material. Suitable materials include, for example, silicon dioxide, silicon oxynitride, silicon nitride, or combinations thereof. A gap fill layer 650 of nitrogen doped amorphous carbon material is then deposited on the sidewall spacers 640 and patterned nitrogen doped amorphous carbon layer 621 structures as shown in FIG. 6E. The nitrogen doped amorphous carbon material may be deposited by any of the processes described herein. The gap fill layer 650 is then etched back to expose the sidewall spacers 640 as shown in FIG. 6F. The sidewall spacers 640 are then etched to expose the base material 610 defining a hardmask layer 651 as shown in FIG. 6G. The base material 610 may then be patterned etched to form a patterned base material 611 as shown in FIG. 6H.

In an alternative process, after the sidewall spacers 640 are formed adjacent the patterned nitrogen doped amorphous carbon layer 621 structures as shown in FIG. 6D, the patterned nitrogen doped amorphous carbon layer 621 is then stripped from the substrate surface. The sidewall spacers 640 then form a pattern as shown in FIG. 6E′, which may be used as a hardmask for the base material 610. The base material 610 may then be patterned etched to form a patterned base material 611.

While the foregoing is directed to embodiments of the present invention, other and further embodiments of the invention may be devised without departing from the basic scope thereof, and the scope thereof is determined by the claims that follow.

1. A method of forming a nitrogen doped amorphous carbon layer on a substrate, comprising:
positioning a substrate in a substrate processing chamber;
introducing a nitrogen containing hydrocarbon source into the processing chamber;
introducing a hydrocarbon source into the processing chamber;
introducing a plasma-initiating gas into the processing chamber;
heating the substrate to a temperature of between about 200° C. and about 650° C. during the process of forming a nitrogen doped amorphous carbon layer on the substrate;
generating a plasma in the processing chamber; and
forming a nitrogen doped amorphous carbon layer on the substrate.

2. The method of claim 1, wherein the nitrogen containing hydrocarbon source is described by the formula CₓH_{y}N_{z}, where x has a range of between 1 and 12, y has a range of between 2 and 20, and z has a range of between 1 and 10

3. The method of claim 1, wherein the nitrogen containing hydrocarbon source is selected from the group comprising: methylamine, dimethylamine, trimethylamine (TMA), triethylamine, aniline, pyridine, benzonitrile, and combinations thereof.

4. The method of claim 1, wherein the hydrocarbon source is described by the formula CₓH_{y}, where x has a range of between 1 and 10 and y has a range of between 2 and 30.

5. The method of claim 3, wherein the hydrocarbon source is selected from the group comprising acetylene (C₂H₂), propylene (C₃H₆), propyne (C₃H₄), propane (C₃H₈), butane (C₄H₁₀), butylene (C₄H₈), butadiene (C₄H₆), vinylacetylene, phenylacetylene, and combinations thereof.

6. The method of claim 1, wherein the ratio of the molar flow rate of the hydrocarbon source and the molar flow rate of the nitrogen containing hydrocarbon source is between about 1:5 to about 3:1.

7. The method of claim 1, wherein the as-deposited nitrogen doped amorphous carbon layer has an adjustable carbon:nitrogen ratio that ranges from about 0.1% nitrogen to about 4.0% nitrogen.

8. The method of claim 1, wherein the pressure in the substrate processing chamber is about 0.5 Torr to 20 Torr during the process of forming a nitrogen doped amorphous carbon layer on the substrate.

9. The method of claim 1, wherein the nitrogen doped amorphous carbon layer is formed to have a density of about 1.5 g/cc to about 2.2 g/cc.

10. The method of claim 11, wherein the temperature is between about 300° C. and about 550° C.

11. A method of forming a device comprising:
forming one or more nitrogen doped amorphous carbon layers on a substrate by:
positioning a substrate in a deposition chamber,
providing a gas mixture to the deposition chamber, wherein the gas mixture comprises a nitrogen containing hydrocarbon source, one or more hydrocarbon compounds and an inert gas, wherein the substrate is heated to a temperature between about 200° C. and about 600° C.; and
generating a plasma in the processing chamber to decompose the one or more hydrocarbon compounds and the nitrogen containing hydrocarbon source in the gas mixture to form the one or more nitrogen doped amorphous carbon layers on the substrate;
defining a pattern in at least one region of the one or more nitrogen doped amorphous carbon layers; and
transferring the pattern defined in the at least one region of the one or more nitrogen doped amorphous carbon layers into the substrate using the one or more nitrogen doped amorphous carbon layers as a mask.

12. The method of claim 11, wherein the nitrogen doped hydrocarbon source is described by the formula Cₓ_{y}N_{z}, where x has a range of between 1 and 12, y has a range of between 2 and 20, and z has a range of between 1 and 10

13. The method of claim 12, wherein the nitrogen doped hydrocarbon source is selected from the group comprising: methylamine, dimethylamine, trimethylamine (TMA), triethylamine, aniline, pyridine, benzonitrile, and combinations thereof.

14. The method of claim 11 wherein the one or more hydrocarbon compounds in the gas mixture have the general formula CxHy, wherein x has a range of 2 to 4 and y has a range of 2 to 10.

15. The method of claim 14 wherein the one or more hydrocarbon compounds is selected from the group consisting of propylene (C₃H₆), propyne (C₃H₄), propane (C₃H₈), butane (C₄H₁₀), butylene (C₄H₈), butadiene (C₄H₆), acetelyne (C₂H₂) and combinations thereof.

16. The method of claim 11 wherein the nitrogen doped amorphous carbon layer has a carbon: hydrogen ratio in the range of 5% hydrogen to 50% hydrogen.

17. The method of claim 11 wherein the inert gas is selected from the group consisting of helium, argon and combinations thereof.

18. The method of claim 11 wherein the temperature is between about 300° C. and about 550° C.

19. The method of claim 11 wherein the deposition chamber is maintained at a pressure between 0.5 Torr to 20 Torr.

20. The method of claim 11, wherein the nitrogen doped hydrocarbon source is trimethylamine, the one or more hydrocarbon compounds is acetylene, and the inert gas is a mixture comprising helium and argon.
